(19) United States
(12) Patent Application Publication
(10) Pub. No.: US 2025/0391745 A1
(43) Pub. Date: Dec. 25, 2025

(54) PACKAGE STRUCTURE AND PACKAGE METHOD

(71) Applicant: JCET Group Co., Ltd., Jiangyin (CN)

(72) Inventors: Kaiyuan YU, Jiangyin (CN); Hao ZHOU, Jiangyin (CN); Jiaming YIN, Jiangyin (CN)

(73) Assignee: JCET Group Co., Ltd., Jiangyin (CN)

(21) Appl. No.: 19/220,721

(22) Filed: May 28, 2025

(30) Foreign Application Priority Data
Jun. 25, 2024 (CN) 202410844293.5

(51) Int. Cl. H01L 23/495; H01L 21/56; H01L 23/00; H01L 23/31

(52) U.S. Cl. CPC H01L 23/4952; H01L 21/56; H01L 23/3107; H01L 23/49541; H01L 24/48; H01L 24/85; H01L 2224/48245; H01L 2224/85

(57) ABSTRACT

A package structure includes a lead frame including a first surface, wherein the lead frame includes a base and first leads located on its four sides, a first chip provided on a first surface of the base, and a first conductive wire located on a first surface of the lead frame and spanning the first chip. Two ends of the first conductive wire are electrically connected with the first leads on opposing two sides of the base.

### CROSS-REFERENCE TO RELATED APPLICATIONS

This application claims the benefit of priority to Chinese Application No. 202410844293.5, filed on Jun. 25, 2024, which is hereby incorporated by reference in its entirety.

### TECHNICAL FIELD

The present disclosure relates to the field of semiconductor package, and particularly relates to a package structure and a package method.

### BACKGROUND

With the high-speed development of science and technology and the electronics industry, various digital and high-frequency electronic components radiate a large amount of electromagnetic waves of different frequencies and wavelengths into space during operation. Electromagnetic radiation and electromagnetic waves not only interfere with the realization of the performance of electronic components, but also cause serious harm to human beings and other living things. With the development of 5G technology, the demand for electromagnetic shielding devices in communication and consumer electronics continues to grow, and at the same time, the requirements for electromagnetic shielding are getting higher and higher. Therefore, electromagnetic shielding has become a necessary process for electronic components.

After the molding is completed, the package structure will continue to be mounted with an electromagnetic shielding metal cover to cover the package structure, so as to serve for electromagnetic shielding.

### SUMMARY

Embodiments of the present disclosure provide a package structure, comprising: a lead frame, the lead frame comprises a first surface, and the lead frame comprises a base and a first lead located on its four sides; a first chip, provided on the first surface of the base; a first conductive wire, located on the first surface of the lead frame and spanning the first chip, and two ends of the first conductive wire are electrically connected with the first lead, respectively.

Embodiments of the present disclosure also provide a package method, comprising: providing a lead frame, the lead frame comprising a first surface, the lead frame comprising a base and first leads located on two sides thereof; providing a first chip on the first surface of the base; forming, on the first surface of the lead frame, a plurality of first conductive wires spanning the first chip, and the two ends of the first conductive wires are electrically connected with the first leads, respectively.

### BRIEF DESCRIPTION OF THE DRAWINGS

FIGS. 1-3 are structural schematic diagrams corresponding to the first embodiment of the package structure of the present disclosure;

FIGS. 4-6 are structural schematic diagrams corresponding to the second embodiment of the package structure of the present disclosure;

FIGS. 7-9 are structural schematic diagrams corresponding to the third embodiment of the package structure of the present disclosure;

FIGS. 10-17 are structural schematic diagrams corresponding to each step of the first embodiment of the package method of the present disclosure;

FIGS. 18-22 are structural schematic diagrams corresponding to each step of the second embodiment of the package method of the present disclosure;

FIGS. 23-26 are structural schematic diagrams corresponding to each step of the third embodiment of the package method of the present disclosure; and

FIG. 27 is a flow chart of a package method of the present disclosure.

### DETAILED DESCRIPTIONS

As can be seen from the background technology, currently, the electromagnetic shielding effect is achieved by mounting an electromagnetic shielding metal cover to cover the package structure. However, the electromagnetic shielding metal cover has a thicker thickness, resulting in the overall thickness of the package structure being too large, which is not conducive to the miniaturization of the volume of the package structure and affects the performance of the package structure.

In order to solve the above technical problem, the present disclosure provides a package method, comprising: providing a lead frame, the lead frame comprising a first surface, the lead frame comprising a base and first leads located on its four sides; providing a first chip on the first surface of the base; forming a plurality of first conductive wires spanning the first chip on the first surface of the lead frame, and the two ends of the first conductive wires are electrically connected with the first leads on opposing two sides of the base, respectively.

In the package method provided by the embodiments of the present disclosure, a lead frame is provided which includes a first surface, the lead frame includes a base and first leads located on four sides thereof, and a first chip is provided on the first surface of the base, a plurality of first conductive wires spanning the first chip are formed on the first surface of the lead frame, and the two ends of the first conductive wires are electrically connected with the first leads on opposing two sides of the base, respectively; in the embodiment of the present disclosure, a plurality of the first conductive wire spanning the first chip are formed on the first surface of the lead frame, the plurality of the first conductive wire approximately form a continuous conductive surface, the continuous conductive surface has the ability to block the electromagnetic wave penetration, reducing the probability of the first chip being interfered by electromagnetic interference; at the same time, after the subsequent formation of the molding layer, the molding layer can cover the plurality of the first conductive wire; compared to the solution of providing an electromagnetic shielding cover at the periphery of the molding layer, the molding layer according to embodiments of the present disclosure covers a plurality of first conductive wires, so that a plurality of first conductive wires are located in the molding layer, and the plurality of first conductive wires serve as an electromagnetic shielding effect, and meanwhile also reduce the thickness of the package structure, which is conducive to the miniaturization of the volume of the package structure, and thus improves the performance of the package structure.

In order to make the above objectives, features and advantages of the embodiments of the present disclosure more clear and understandable, the specific embodiments of the present disclosure are described in detail below in conjunction with the accompanying drawings.

The technical solution of the embodiments of the present disclosure has the following advantages.

In the package method provided by the embodiments of the present disclosure, a lead frame is provided, the lead frame comprising a first surface, the lead frame comprises a base and first leads located on its two sides, and a first chip is provided on the first surface of the base, a plurality of first conductive wires span the first chip are formed on the first surface of the lead frame, and the two ends of the first conductive wires are electrically connected with the first leads on opposing two sides of the base, respectively; in the embodiment of the present disclosure, a plurality of the first conductive wire spanning the first chip are formed on the first surface of the lead frame, the plurality of the first conductive wire approximately form a continuous conductive surface, the continuous conductive surface has the ability to block electromagnetic wave penetration, reducing the probability of the first chip being interfered by electromagnetic interference; at the same time, after the subsequent formation of the molding layer, the molding layer can cover the plurality of the first conductive wire; compared to the solution of providing an electromagnetic shielding cover at the periphery of the molding layer, the embodiment of the present disclosure covers a plurality of first conductive wires with the molding layer, so that a plurality of first conductive wires are located in the molding layer, and a plurality of first conductive wires serve as an electromagnetic shielding, and at the same time also reduce the thickness of the package structure, which is conducive to the miniaturization of the volume of the package structure, and thus improves the performance of the package structure.

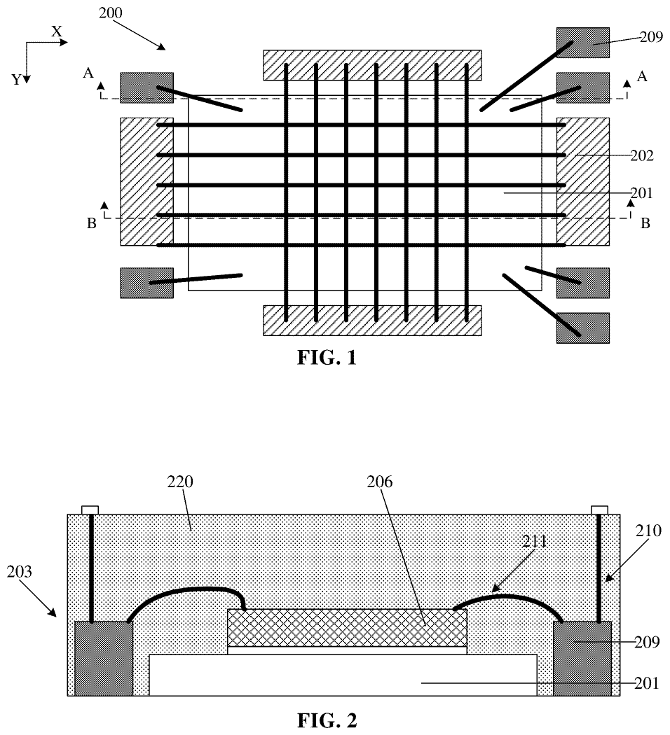

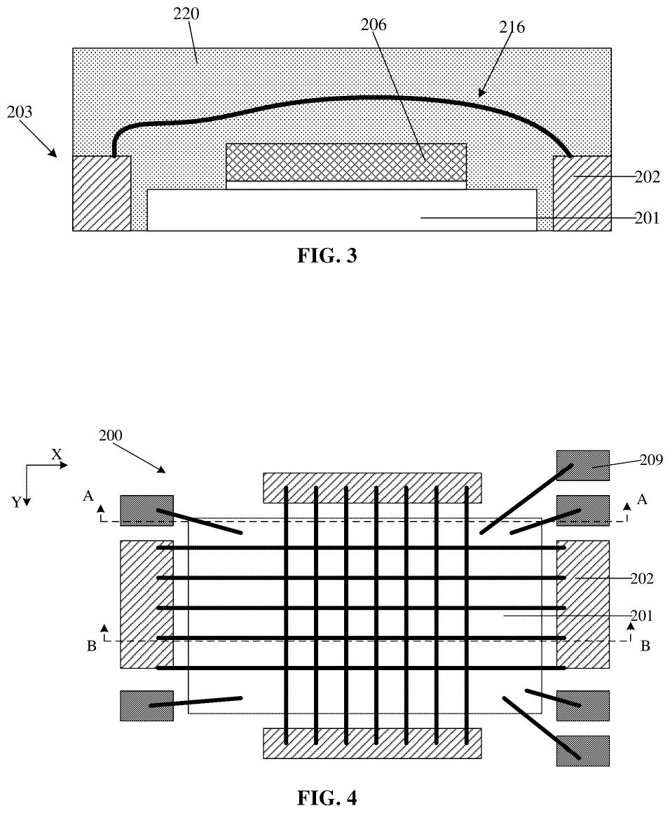

FIGS. 1-3 are structural schematic diagrams corresponding to the first embodiment of the package structure of the present disclosure. FIG. 1 is a top view, FIG. 2 is a sectional view of FIG. 1 along the direction AA, and FIG. 3 is a sectional view of FIG. 1 along the direction BB.

The package structure comprises a lead frame 200, the lead frame 200 comprising a first surface 203, the lead frame 200 comprising a base 201 and first leads 202 located on its four sides; a first chip 206, provided on the first surface 203 of the base 201; a first conductive wire 216, located on the first surface 203 of the lead frame 200 and spanning the first chip 206, two ends of the first conductive wire 216 being electrically connected with the first lead 202 on opposite sides of the base.

It should be noted that, a plurality of first conductive wires 216 spanning the first chip 206 are provided on the first surface 203 of the lead frame 200, the plurality of first conductive wires 216 approximately form a continuous conductive surface, and the continuous conductive surface has the ability to block the electromagnetic wave penetration, which reduces the probability that the first chip 206 undergoes electromagnetic interference, and at the same time, after the molding layer is provided, the molding layer can cover the plurality of first conductive wires 216; compared to the solution of providing an electromagnetic shielding cover at the periphery of the molding layer, the molding layer according to embodiments of the present disclosure covers the plurality of first conductive wires 216, so that the plurality of first conductive wires 216 are located in the molding layer, and the plurality of first conductive wires 216 act as an electromagnetic shielding, and at the same time, also reduce the thickness of the package structure, and it is conducive to the miniaturization of the volume of the package structure, thereby improving the performance of the package structure.

Specifically, the lead frame 200 provides a process platform for providing the first chip 206 on the lead frame 200, and at the same time, the reliability of the lead frame 200 is relatively high, so that the overall reliability of the first chip 206 provided on the lead frame 200 is also greatly improved, and after the molding layer is set, the bonding strength between the molding layer and the lead frame 200 is high, and the airtightness of the package structure is better.

It should be noted that the first surface 203 of the lead frame 200 is used as a carrier surface for placing the first chip 206.

In the present embodiment, the first surface 203 of the base 201 is lower than the first surface 203 of the first lead 202.

Specifically, the first surface 203 of the base 201 is lower than the first surface 203 of the first lead 202, which means that the height of the base 201 is lower than the height of the first lead 202, and in the process of providing the first chip 206, it is possible to enable the first chip 206 to be located in the lead frame 200, so that the overall height of the lead frame 200 and the first chip 206 can be reduced, thereby further reducing the thickness of the package structure.

In the present embodiment, the lead frame 200 comprises a base 201 and first leads 202 located on its four sides.

It should be noted that the base 201 provides a support and stabilization ability for placing the first chip 206, and the first lead 202 is used to electrically connect with the second conductive wire provided subsequently.

In the present embodiment, the lead frame 200 further comprises a second lead 209, the second lead 209 is provided between adjacent first leads 202.

Specifically, the second lead 209 is used to electrically connect with the first chip 206 so that the first chip 206 has an input/output port that can maintain the normal operation of the first chip 206.

As an example, the first surface 203 of the second lead 209 is flush with the first surface 203 of the first lead 202.

It should be noted that the first surface 203 of the second lead 209 is flush with the first surface 203 of the first lead 202, which means that the first surface 203 of the second lead 209 is higher than the first surface 203 of the base 201, and after the first chip 206 is provided on the base 201, it is possible to reduce the difference in height between the first chip 206 and the second lead 209, and in the process of subsequently providing the second conductive wire, it is possible to shorten the connection distance between the first chip 206 and the second lead 209, which means that the length of the second conductive wire can be reduced, reducing the process difficulty of forming the second conductive wire by the wire bonding process.

It should be noted that the first chip 206 is used to meet the performance needs of the package structure. Specifically, the first chip 206 with different functions may be selected according to the performance needs of the package structure.

In the present embodiment, the first conductive wire 216 comprises a first sub conductive wire (not labeled) extending along a first direction (shown as the X direction in FIG. 1) and a second sub conductive wire (not labeled) extending along a second direction (shown as the Y direction in FIG. 1), the first direction being perpendicular to the second direction.

It should be noted that the first sub conductive wire and the second sub conductive wire are perpendicular to each other, which means that a continuous conductive surface extending along the first direction and a continuous conductive surface extending along the second direction are formed above the first chip 206, thereby further reducing the probability of the electromagnetic wave passing through the conductive surface.

In the present embodiment, the first sub conductive wire and the second sub conductive wire located above the first chip 206 are orthogonal to each other.

Specifically, the first sub conductive wire and the second sub conductive wire located above the first chip 206 are orthogonal to each other, which means that a conductive surface with a grid-like shape is formed above the first chip 206, and this grid-like conductive surface can form an electromagnetic shielding layer above the first chip 206, and this electromagnetic shielding layer can block the electromagnetic waves from penetrating, thus reducing the probability of the first chip 206 undergoing electromagnetic interference.

In the present embodiment, the material of the first conductive wire 216 includes copper.

In the present embodiment, the package structure further comprises a second conductive wire 211, located on the first surface 203 of the lead frame 200, one end of the second conductive wire 211 being electrically connected with the first chip 206, and the other end of the second conductive wire 211 being electrically connected with the second lead 209.

It should be noted that one end of the second conductive wire 211 is used to be electrically connected with the first chip 206 and the other end of the second conductive wire 211 is electrically connected with the second lead 209, thereby enabling the first chip 206 to be electrically connected with an external circuit carrier board via the second conductive wire 211 and the second lead 209.

In the present embodiment, the package structure further comprises a first conductive structure 210, located on a first surface 203 of the second lead 209, the first conductive structure 210 being electrically connected with the second lead 209.

It should also be noted that the first conductive structure 210 is used to be electrically connected with the second lead 209, and the first chip 206 can be electrically connected with other circuit components through the top of the first conductive structure 210; in addition, the top of the first conductive structure 210 and the base 201 are exposed from the two opposing surfaces of the molding layer, respectively, and also can be subsequently mounted to an external circuit carrier board through the top of the first conductive structure 210, while allowing the base to dissipate heat upwardly. Furthermore, a heat sink can be provided on the base to further improve its heat dissipation capability.

As an example, the first conductive structure 210 comprises a conductive wire.

Specifically, when the first conductive structure 210 is a conductive wire, the first conductive wire 216, second conductive wire 211, and first conductive structure 210 are formed in the same step in the package method.

In other embodiments, the first conductive structure 210 may also be an electrical connection pillar.

As an example, when the first conductive structure 210 is an electrical connection pillar, the first conductive wire 216 and second conductive wire 211 are formed in the same step in the package method; after forming the first conductive wire 216 and the second conductive wire 211, the first conductive structure 210 is formed on the first surface 203 of the second lead 209.

In the present embodiment, the package structure further comprises a first molding layer 220, located on a first surface 203 of the lead frame 200 and covering the first conductive wire 216, the second conductive wire 211, the first conductive structure 210, and the first chip 206.

It should be noted that the first molding layer 220 is used to envelop the first conductive wire 216, the second conductive wire 211, the first conductive structure 210, and the first chip 206 on the first surface 203, thus providing protection for the first conductive wire 216, the second conductive wire 211, the first conductive structure 210, and the first chip 206, and at the same time reducing the probability that the first conductive wire 216, the second conductive wire 211 and the first conductive structure 210 cross-talk with each other, and also reducing the probability that the first conductive wire 216, the second conductive wire 211, the first conductive structure 210 and the first chip 206 are contaminated.

In the present embodiment, one end of the first conductive structure 210 is connected with the second lead 209, and another end is exposed from the first molding layer 220. Specifically, one end of the first conductive structure 210 away from the second lead 209 is exposed from the first molding layer 220, and the first chip 206 may be electrically connected with an external circuit carrier board or other circuit components through the first conductive structure 210. In the present embodiment, the material of the first molding layer 220 comprises a molding compound. Specifically, the material of the molding compound comprises an epoxy resin, and the epoxy resin has the advantages of low shrinkage, good adhesion, good corrosion resistance, excellent electrical properties, low cost, etc. It should be noted that the material of the molding compound may also comprise one or more of a hardener, a catalyst, and a filler.

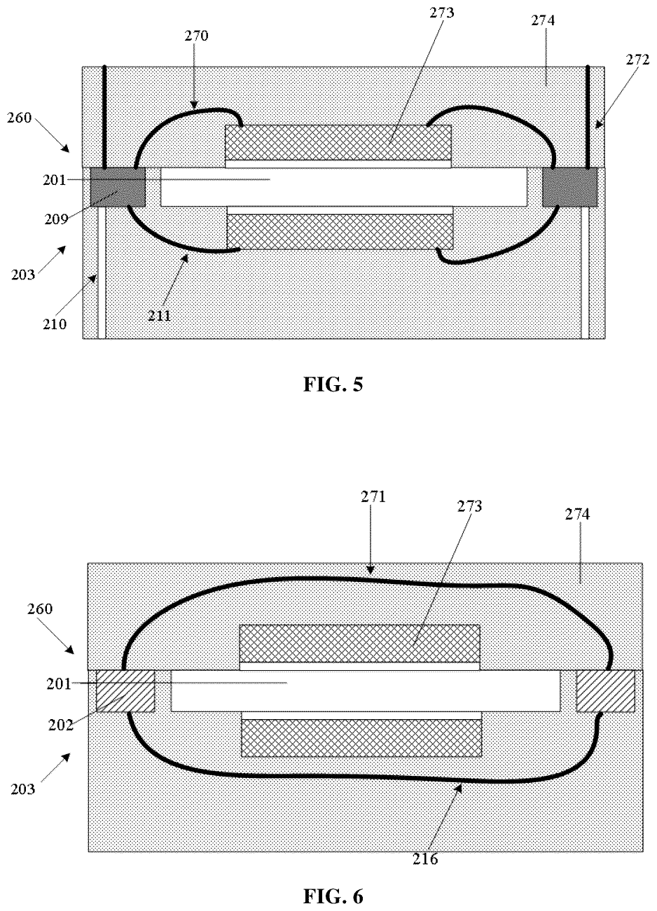

FIGS. 4-6 are structural schematic diagrams corresponding to the second embodiment of the package structure of the present disclosure. FIG. 4 is a top view, FIG. 5 is a sectional view of FIG. 4 along the direction AA, and FIG. 6 is a sectional view of FIG. 4 along the direction BB.

The similar content between the present embodiment and the first embodiment is not repeated herein. The difference between the present embodiment and the first embodiment lies in that:

Referring to FIG. 5, the first surface 203 of the base 201 is flush with the first surface 203 of the first lead 202.

Specifically, the first surface 203 of the base 201 is flush with the first surface 203 of the first lead 202, simplifying the manufacturing process of the lead frame 200.

In the present embodiment, the lead frame 200 further comprises a second surface 260 facing away from the first surface 203, the second surface 260 of the base 201 being flush with the second surface 260 of the first lead 202.

Specifically, the second surface 260 of the base 201 is flush with the second surface 260 of the first lead 202, simplifying the manufacturing process of the lead frame 200.

In the present embodiment, the package structure further comprises: a second chip 273, provided on a second surface 260 of the base 201.

It should be noted that the second chip 273 is used to meet the performance needs of the package structure. Specifically, the second chip 273 may be selected to have different functions according to the performance needs of the package structure.

In the present embodiment, the package structure further comprises a third conductive wire 271 located on a second surface 260 of the lead frame 200 and spanning the second chip 273, two ends of the third conductive wire 271 being electrically connected with the first leads 202, respectively.

It should be noted that the plurality of third conductive wires 271 approximately form a continuous conductive surface, and the continuous conductive surface has the ability to block the penetration of electromagnetic waves, which reduces the probability of the second chip 273 being subjected to electromagnetic interference, and at the same time, after the second molding layer 274 is provided, the second molding layer 274 is able to cover the plurality of third conductive wires 271; compared to the solution of providing an electromagnetic shielding cover at the periphery of the second molding layer 274, the second molding layer 274 according to the embodiments of the present disclosure covers a plurality of third conductive wires 271, so that a plurality of third conductive wires 271 are located in the second molding layer 274, and the plurality of third conductive wires 271 act as electromagnetic shielding, and at the same time also reduce the thickness of the package structure, which is conducive to the miniaturization of the volume of the package structure, and thereby increasing the performance of the package structure.

Moreover, by forming the third conductive wire 271 on the second surface 260, it also allows electromagnetic shielding for both the first surface 203 and the second surface 260 of the package structure.

In the present embodiment, the third conductive wire 271 comprises a third sub conductive wire (not labeled) extending along a first direction (shown as the X direction in FIG. 4) and a fourth sub conductive wire (not labeled) extending along a second direction (shown as the Y direction in FIG. 4), the first direction being perpendicular to the second direction.

It should be noted that the third sub conductive wire and the fourth sub conductive wire are perpendicular to each other, which means that a continuous conductive surface extending along the first direction and a continuous conductive surface extending along the second direction are formed above the second chip 273, which further reduces the probability of the electromagnetic wave passing through the conductive surface.

In the present embodiment, the third sub conductive wire and the fourth sub conductive wire located above the second chip 273 are orthogonal to each other.

Specifically, the third sub conductive wire and the fourth sub conductive wire located above the second chip 273 are orthogonal to each other, which means that a conductive surface with a grid-like shape is formed above the second chip 273, and it is capable of forming an electromagnetic shielding layer above the second chip 273, and this electromagnetic shielding layer is capable of blocking the electromagnetic waves from penetrating, and reducing the probability that the second chip 273 undergoes electromagnetic interference.

In the present embodiment, the package structure further comprises a fourth conductive wire 270 located on a second surface 260 of the lead frame 200, one end of the fourth conductive wire 270 being electrically connected with the second chip 273, and the other end of the fourth conductive wire 270 being electrically connected with the second lead.

It should be noted that one end of the fourth conductive wire 270 is used to electrically connect with the second chip 273, and the other end of the fourth conductive wire 270 is electrically connected with the second lead, thereby enabling the second chip 273 to be electrically connected with an external circuit carrier board via the fourth conductive wire 270 and the second lead.

In the present embodiment, the package structure further comprises a second conductive structure 272 located on a second surface 260 of the second lead, the second conductive structure 272 being electrically connected with the second lead.

In the present embodiment, the second conductive structure 272 comprises a conductive wire.

Specifically, when the first conductive structure 210 is a conductive wire, the third conductive wire 271, the fourth conductive wire 270, and the second conductive structure 272 are formed in the same step.

In other embodiments, the second conductive structure 272 may also comprise an electrical connection pillar.

Specifically, when the second conductive structure 272 is an electrical connection pillar, the third conductive wire 271 and the fourth conductive wire 270 are formed in the same step; after the third conductive wire 271 and fourth conductive wire 270 are formed, the second conductive structure 272 is formed on the first surface 203 of the second lead.

In the present embodiment, the package structure further comprises a second molding layer 274 located on the second surface 260 of the lead frame 200 and covering the third conductive wire 271, the fourth conductive wire 270, the second conductive structure 272, and the second chip 273.

Specifically, the second molding layer 274 is used to envelop the third conductive wire 271, the fourth conductive wire 270, the second conductive structure 272 and the second chip 273 on the second surface 260, thus providing protection for the third conductive wire 271, the fourth conductive wire 270, the second conductive structure 272 and the second chip 273, and at the same time reducing the probability that the third conductive wire 271, the fourth conductive wire 270 and the second conductive structure 272 cross-talk with each other, and also reducing the probability that the third conductive wire 271, the fourth conductive wire 270, the second conductive structure 272, and the second chip 273 are contaminated.

In the present embodiment, one end of the second conductive structure 272 is connected with the second lead 209, and the other end is exposed from the second molding layer 274. Specifically, one end of the second conductive structure 272 away from the second lead 209 is exposed from the second molding layer 274, and the second chip 273 may be electrically connected with an external circuit carrier board or other circuit components via the second conductive structure 272.

In the present embodiment, the material of the second molding layer 274 comprises a molding compound. Specifically, the material of the molding compound comprises an epoxy resin, and the epoxy resin has the advantages of low shrinkage, good adhesion, good corrosion resistance, excellent electrical properties, low cost, etc. It should be noted that the material of the molding compound may also comprise one or more of a hardener, a catalyst, and a filler.

It should be noted that in the package method, the first molding layer and the second molding layer 274 are formed in different steps, respectively.

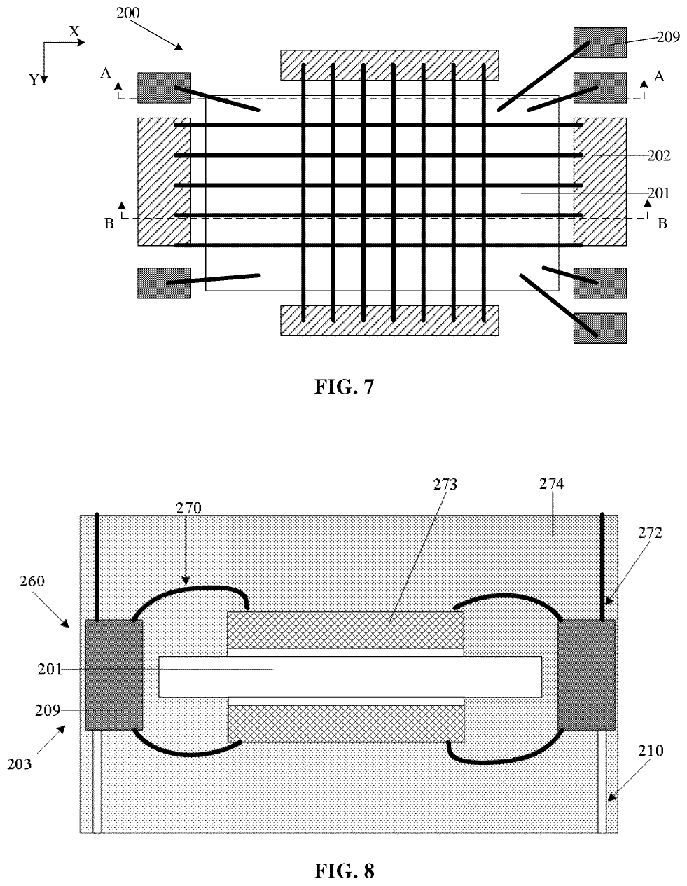

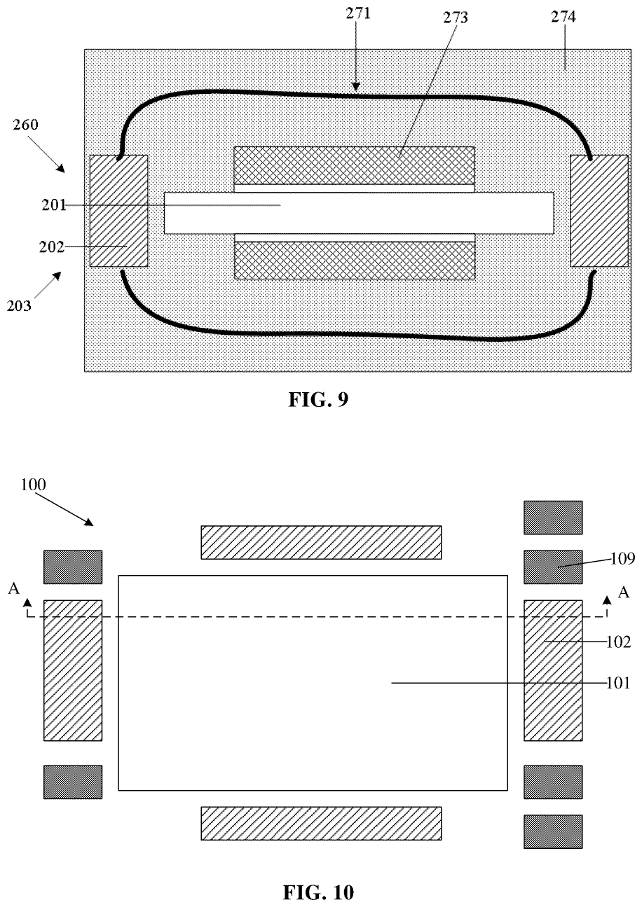

FIGS. 7-9 are structural schematic diagrams corresponding to the third embodiment of the package structure of the present disclosure. FIG. 7 is a top view, FIG. 8 is a sectional view of FIG. 7 along the direction AA, and FIG. 9 is a sectional view of FIG. 7 along the direction BB.

The similar content between the present embodiment and the first embodiment is not repeated herein. The difference between the present embodiment and the first embodiment lies in that:

Referring to FIGS. 8-9, the lead frame 200 further comprises a second surface 260 facing away from the first surface 203. The second surface 260 of the base 201 is higher than the second surface 260 of the first lead 202.

Specifically, the second surface 260 of the base 201 is higher than the second surface 260 of the first lead 202, which means that the thickness of the base 201 is smaller than the thickness of the first lead 202, and in the process of providing the second chip, it is able to locate the second chip in the lead frame 200, so that the overall height of the lead frame 200 and the second chip can be reduced, which further reduces the thickness of the package structure.

In the present embodiment, the package structure further comprises a third conductive wire 271 located on a second surface 260 of the lead frame 200 and spanning the second chip 273, with two ends of the third conductive wire 271 being electrically connected with the first lead 202, respectively.

It should be noted that the plurality of third conductive wires 271 approximately form a continuous conductive surface, and the continuous conductive surface has the ability to block the penetration of electromagnetic waves, which reduces the probability of the second chip 273 being subjected to electromagnetic interference, and at the same time, after providing the second molding layer, the second molding layer is able to cover the plurality of third conductive wires 271, and compared to the providing of electromagnetic shielding cover at the periphery of the second molding layer, the second molding layer according to the embodiments of the present disclosure covers a plurality of third conductive wires 271, so that a plurality of third conductive wires 271 are located in the third molding layer, and the plurality of third conductive wires 271 can serve electromagnetic shielding effect, at the same time reducing the thickness of the package structure, which is conducive to the miniaturization of the volume of the package structure and thus improves the performance of the package structure.

Moreover, by forming the third conductive wire 271 on the second surface 260, both the first surface 203 and the second surface 260 of the package structure have the function of electromagnetic shielding.

In the present embodiment, the third conductive wire 271 comprises a third sub conductive wire (not labeled) extending along a first direction (shown as the X direction in FIG. 7) and a fourth sub conductive wire (not labeled) extending along a second direction (shown as in the Y direction in FIG. 7), the first direction being perpendicular to the second direction.

It should be noted that the third sub conductive wire and the fourth sub conductive wire are perpendicular to each other, which means that a continuous conductive surface extending along the first direction and a continuous conductive surface extending along the second direction are formed above the second chip 273, which further reduces the probability of the electromagnetic wave passing through the conductive surface.

In the present embodiment, the third sub conductive wire and the fourth sub conductive wire located above the second chip 273 are orthogonal to each other.

Specifically, the third sub conductive wire and the fourth sub conductive wire located above the second chip 273 are orthogonal to each other, which means that a conductive surface with a grid-like shape is formed above the second chip 273, and it is capable of forming an electromagnetic shielding layer above the second chip 273, this electromagnetic shielding layer is capable of blocking the electromagnetic waves from penetrating, and reducing the probability that the second chip 273 is subjected to electromagnetic interference.

In the present embodiment, the package structure further comprises a fourth conductive wire 270, located on a second surface 260 of the lead frame 200, one end of the fourth conductive wire 270 being electrically connected with the second chip 273, and the other end of the fourth conductive wire 270 being electrically connected with the second lead.

It should be noted that one end of the fourth conductive wire 270 is used to electrically connect with the second chip 273, and the other end of the fourth conductive wire 270 is electrically connected with the second lead, thereby enabling the second chip 273 to be electrically connected with an external circuit carrier board or other circuit component via the fourth conductive wire 270 and the second lead.

In the present embodiment, the package structure further comprises a second conductive structure 272, provided on a second surface 260 of the second lead. The second conductive structure 272 is electrically connected with the second lead.

In the present embodiment, the second conductive structure 272 comprises a conductive wire.

Specifically, when the first conductive structure 210 is a conductive wire, the third conductive wire 271, the fourth conductive wire 270, and the second conductive structure 272 are formed in the same step.

In other embodiments, the second conductive structure 272 may also comprise an electrical connection pillar.

Specifically, when the second conductive structure 272 is an electrical connection pillar, the third conductive wire 271 and the fourth conductive wire 270 are formed in the same step; after forming the third conductive wire 271 and the fourth conductive wire 270, the second conductive structure 272 is formed on the first surface 203 of the second lead.

In the present embodiment, the package structure further comprises a second molding layer 274 located on the second surface 260 of the lead frame 200 and covering the third conductive wire 271, the fourth conductive wire 270, the second conductive structure 272, and the second chip 273.

Specifically, the second molding layer 274 is used to cover the third conductive wire 271, the fourth conductive wire 270, the second conductive structure 272, and the second chip 273 on the second surface 260, thus providing protection for the third conductive wire 271, the fourth conductive wire 270, the second conductive structure 272, and the second chip 273, and at the same time reducing the probability that the third conductive wire 271, the fourth conductive wire 270, and the second conductive structure 272 cross-talk with each other, and also reducing the probability of the third conductive wire 271, the fourth conductive wire 270, the second conductive structure 272, and the second chip 273 being contaminated.

In the present embodiment, one end of the second conductive structure 272 is connected with the second lead 209, and the other end is exposed from the second molding layer 274. Specifically, the end of the second conductive structure 272 away from the second lead 209 is exposed from the second molding layer 274, and the second chip 273 may be electrically connected with an external circuit carrier board or other circuit components via the second conductive structure 272.

In the present embodiment, the material of the second molding layer 274 comprises a molding compound. Specifically, the material of the molding compound comprises an epoxy resin, and the epoxy resin has the advantages of low shrinkage, good adhesion, good corrosion resistance, excellent electrical properties, low cost, etc. It should be noted that the material of the molding compound may also comprise one or more of a hardener, a catalyst, and a filler.

It should be noted that the first molding layer and the second molding layer 274 are formed in the same step in the package method.

Accordingly, embodiments of the present disclosure also provide a package method. FIGS. 10-17 are structural schematic diagrams corresponding to each step of the first embodiment of the package method of the present disclosure.

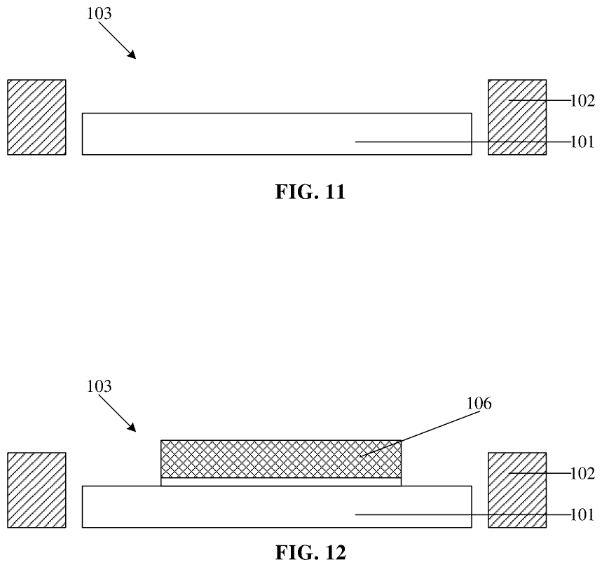

Referring to FIGS. 10-11, FIG. 10 is a top view, and FIG. 11 is a sectional view of FIG. 10 along the direction AA; a lead frame 100 is provided, the lead frame 100 comprising a first surface 103, the lead frame 100 comprising a base 101 and a first lead 102 located on its two sides.

Specifically, the lead frame 100 provides a process platform for subsequently providing the first chip on the lead frame 100, and at the same time, the reliability of the lead frame 100 is relatively high, so that the overall reliability of the first chip provided on the lead frame 100 is also greatly improved, and after the subsequent formation of the molding layer, the bonding strength between the molding layer and the lead frame 100 is high, and the airtightness of the package structure is better.

It should be noted that the first surface 103 of the lead frame 100 is used as a carrier surface for subsequent placement of the first chip.

In the present embodiment, the first surface 103 of the base 101 is lower than the first surface 103 of the first lead 102.

Specifically, the first surface 103 of the base 101 is lower than the first surface 103 of the first lead 102, which means that the height of the base 101 is lower than the height of the first lead 102, which enables the first chip to be located in the lead frame 100 during the subsequent arrangement of the first chip, so that the overall height of the lead frame 100 and the first chip is reduced, thereby further reducing the thickness of the package.

In the present embodiment, the lead frame 100 comprises a base 101 and first leads 102 located on its two sides.

It should be noted that the base 101 provides support and stabilization function for subsequent placement of the first chip, and the first lead 102 is used to be electrically connected with the second conductive wire formed subsequently.

In the present embodiment, in the step of providing the lead frame 100, the lead frame 100 further comprises a second lead 109, the second lead 109 being located on a side of the base 101 and first lead 102.

Specifically, the second lead 109 is used to be electrically connected with the first chip so that the first chip has input/output ports that can maintain the normal operation of the first chip.

As an example, the first surface 103 of the second lead 109 is flush with the first surface 103 of the first lead 102.

It should be noted that the first surface 103 of the second lead 109 is flush with the first surface 103 of the first lead 102, which means that the first surface 103 of the second lead 109 is higher than the first surface 103 of the base 101, and after the first chip is subsequently provided on the base 101, the height difference between the first chip and the second lead can be reduced, and in the process of subsequently forming a second conductive wire electrically connecting the first chip and the second lead 109, the connection distance between the first chip and the second lead 109 can be made shorter, which means that the length of the second conductive wire can be reduced, which reduces the process difficulty of forming the second conductive wire by the wire bonding process.

Referring to FIG. 12, a first chip 106 is provided on a first surface 103 of the base 101.

It should be noted that the first chip 106 is used to meet the performance requirements of the package structure. Specifically, the first chip 106 may be selected to have different functions according to the performance requirements of the package structure.

In the present embodiment, the step of providing the first chip 106 on the first surface 103 of the base 101 comprises: providing the first chip 106; forming an adhesive layer (not labeled) on the first surface 103 of the base 101; and placing the first chip 106 on the first surface 103 of the base 101 with the adhesive layer being positioned between the base 101 and the first chip 106.

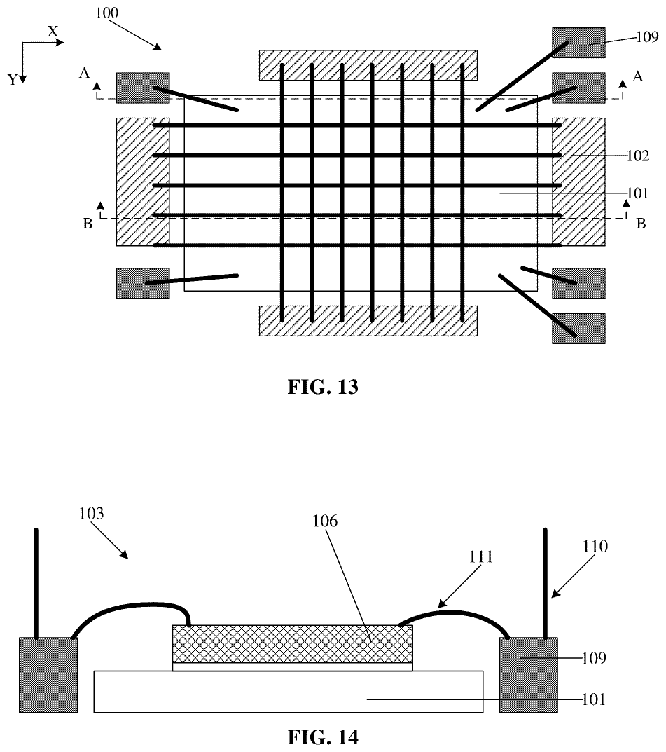

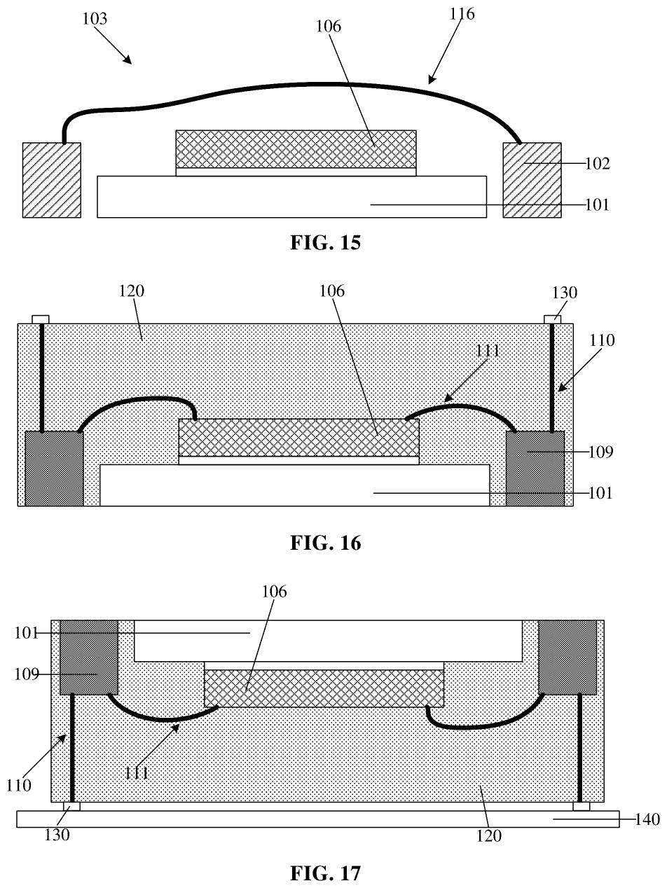

Referring to FIG. 13-15, wherein FIG. 13 is a top view, FIG. 14 is a sectional view of FIG. 13 along the direction AA, and FIG. 15 is a sectional view of FIG. 13 along the direction BB. A plurality of first conductive wires 116 spanning the first chip 106 are formed on the first surface 103 of the lead frame 100, and two ends of the first conductive wires 116 are electrically connected with the first lead 102, respectively.

It should be noted that the plurality of first conductive wires 116 approximately form a continuous conductive surface, and the continuous conductive surface has the ability to block the penetration of electromagnetic waves, which reduces the probability of the first chip 106 being subjected to electromagnetic interference, and at the same time, after the subsequent formation of the molding layer, the molding layer is able to cover the plurality of first conductive wires 116; compared with the solution of providing an electromagnetic shielding cover at the periphery of the molding layer, the molding layer according to embodiments of the present disclosure covers the plurality of first conductive wires 116, so that the plurality of first conductive wires 116 are located in the molding layer, the plurality of first conductive wires 116 act as an electromagnetic shielding, and at the same time, also reduce the thickness of the package structure, which is conducive to the miniaturization of the volume of the package structure, and thus improves the performance of the package structure.

In the present embodiment, in the step of forming the first conductive wire 116, the first conductive wire 116 comprises a first sub conductive wire (not labeled) extending along a first (shown as the X direction in FIG. 13) and a second sub conductive wire (not labeled) extending along a second direction (shown as the Y direction in FIG. 13), the first direction being perpendicular to the second direction.

It should be noted that the first sub conductive wire and the second sub conductive wire are perpendicular to each other, which means that a continuous conductive surface extending along the first direction and a continuous conductive surface extending along the second direction are formed above the first chip 106, thereby further reducing the probability of the electromagnetic wave passing through the conductive surface.

In the present embodiment, the first sub conductive wire and the second sub conductive wire located above the first chip 106 are orthogonal to each other.

Specifically, the first sub conductive wire and the second sub conductive wire located above the first chip 106 are orthogonal to each other, which means that the formation of a conductive surface with a grid-like shape above the first chip 106 is capable of forming an electromagnetic shielding layer above the first chip 106, which is capable of blocking the electromagnetic waves from penetrating and reducing the probability of the first chip 106 being subjected to electromagnetic interference.

In the present embodiment, the material of the first conductive wire 116 comprises copper.

Continuing to refer to FIG. 14, a second conductive wire 111 is formed on the first surface 103 of the lead frame 100, one end of the second conductive wire 111 being electrically connected with the first chip 106, and the other end of the second conductive wire 111 being electrically connected with the second lead 109; a first conductive structure 110 is formed on the first surface 103 of the second lead 109, and the first conductive structure 110 is electrically connected with the second lead 109.

It should be noted that one end of the second conductive wire 111 is used to electrically connect with the first chip 106, and the other end of the second conductive wire 111 is electrically connected with the second lead 109, thereby enabling the first chip 106 to be electrically connected with an external circuit carrier board via the second conductive wire 111 and the second lead 109.

It is also noted that the first conductive structure 110 is used to be electrically connected with the second lead 109, and the first chip 106 may be electrically connected with an external circuit carrier board or other circuit component through the top of the first conductive structure 110.

As an example, the first conductive structure 110 comprises a conductive wire.

In the present embodiment, when the first conductive structure 110 is a conductive wire, the first conductive wire 116, the second conductive wire 111, and the first conductive structure 110 are formed in the same step.

It should be noted that the first conductive wire 116, the second conductive wire 111, and the first conductive structure 110 are all conductive wires and, therefore, can be formed using the same formation process.

Specifically, the first conductive wire 116, the second conductive wire 111, and the first conductive structure 110 are formed in the same step, which can reduce process steps and lower the process cost.

As an example, the process for forming the first conductive wire 116, the second conductive wire 111, and the first conductive structure 110 comprises a wire bonding process.

Referring to FIG. 16, a first molding layer 120 covering the first conductive wire 116, the second conductive wire 111, the first conductive structure 110, and the first chip 106 is formed on the first surface 103 of the lead frame 100.

Specifically, the first molding layer 120 is used to envelop the first conductive wire 116, the second conductive wire 111, the first conductive structure 110, and the first chip 106 on the first surface 103, thus providing protection for the first conductive wire 116, the second conductive wire 111, the first conductive structure 110, and the first chip 106, and at the same time reducing the probability that the first conductive wire 116, the second conductive wire 111, and the first conductive structure 110 cross-talk with each other, and also reducing the probability that the first conductive wire 116, the second conductive wire 111, the first conductive structure 110, and the first chip 106 are contaminated. In the present embodiment, the material of the first molding layer 120 comprises a molding compound. Specifically, the material of the molding compound comprises an epoxy resin, and the epoxy resin has the advantages of low shrinkage, good adhesion, good corrosion resistance, excellent electrical properties, low cost, etc. It should be noted that the material of the molding compound may also comprise one or more of a hardener, a catalyst, and a filler.

It should be noted that after forming the first molding layer 120, it also includes forming a pad 130 on the surface of the first conductive structure 110 exposed by the first molding layer 120.

Specifically, after the package module consisting of the lead frame 100, the first chip 106, and the molding layer is subsequently placed on the carrier board, the pads 130 and the base 201 are exposed from two opposite surfaces of the first molding layer 120, respectively, so as to allow the base 201 to dissipate heat upwardly. Furthermore, a heat sink may be provided on the base 201 to further improve its heat dissipation capability. The pads 130 are used to secure the package module on the carrier board, and at the same time, the pads 130 also serve for electrical conduction, so that the current on the carrier board can flow through the pads 130 into the package module. As an example, the material of the pad 130 comprises tin.

Referring to FIG. 17, a carrier board 140 is provided; a first surface 103 of the lead frame 100 is oriented toward the carrier board 140; and a package module consisting of the lead frame 100, the first chip 106, and the molding layer is placed on the carrier board 140, with the surface of the base 101 facing away from the first surface 103 being exposed from the first molding layer 120.

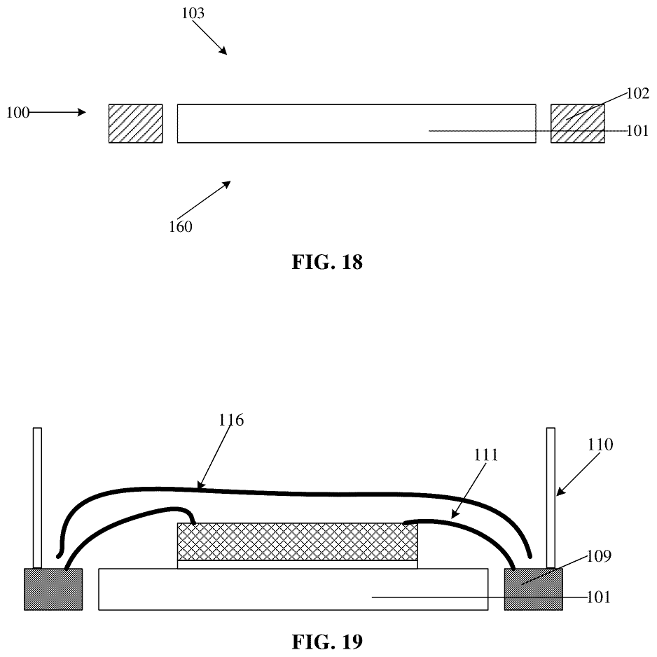

Specifically, placing the package module on the carrier board 140 can improve the integration and functionality of the package structure and make the package structure a wider field of application. And at the same time, placing the package module on the carrier board 140 exposes the pads 130 and the base 201 from the two opposing surfaces of the first molding layer 120, respectively, and allows the base 201 to dissipate heat upwardly. Furthermore, a heat sink may be provided on the base 201 to further improve its heat dissipation capability. FIGS. 18-22 are structural schematic diagrams corresponding to the steps of the second embodiment of the package method of the present disclosure.

The same content between the present embodiment and the first embodiment is not repeated herein. The difference between the present embodiment and the first embodiment lies in that:

Referring to FIG. 18, in the step of providing the lead frame 100, the first surface 103 of the base 101 is flush with the first surface 103 of the first lead 102.

Specifically, the first surface 103 of the base 101 is flush with the first surface 103 of the first lead 102, simplifying the manufacturing process of the lead frame 200.

In the present embodiment, the lead frame 100 further comprises a second surface 160 facing away from the first surface 103, the second surface 160 of the base 101 being flush with the second surface 160 of the first lead 102.

Specifically, the second surface 160 of the base 101 is flush with the second surface 160 of the first lead 102, simplifying the manufacturing process of the lead frame 200.

Referring to FIG. 19, a first conductive structure 110 is formed on the first surface 103 of the second lead 109.

In the present embodiment, the first conductive structure 110 comprises an electrical connection pillar.

It should be noted that the first conductive structure 110 is an electrical connection pillar, and the electrical connection pillar can serve as support while subsequently providing the third conductive wire and the fourth conductive wire on the second surface 160.

In the present embodiment, the process for forming the first conductive structure 110 comprises a pillar planting process.

As an example, when the first conductive structure 110 is an electrical connection pillar, the first conductive wire 116 and the second conductive wire 111 are not formed in the same step; after forming the first conductive wire 116 and the second conductive wire 111, the first conductive structure 110 is formed on the first surface 103 of the second lead 109.

Specifically, the first conductive wire 116 and the second conductive wire 111 are conductive wires, while the first conductive structure 110 is an electrical connection pillar, and therefore, cannot be formed using the same formation process.

In the present embodiment, the first conductive wire 116 and the second conductive wire 111 are formed in the same step, and the process of forming the first conductive wire 116 and the second conductive wire 111 comprises a wire bonding process.

It should be noted that, as shown in FIG. 19, the first conductive wire 116 is shown for ease of illustration, the first conductive wire 116 is not electrically connected with the second lead 109, and the first conductive wire 116 is electrically connected with the first lead 102.

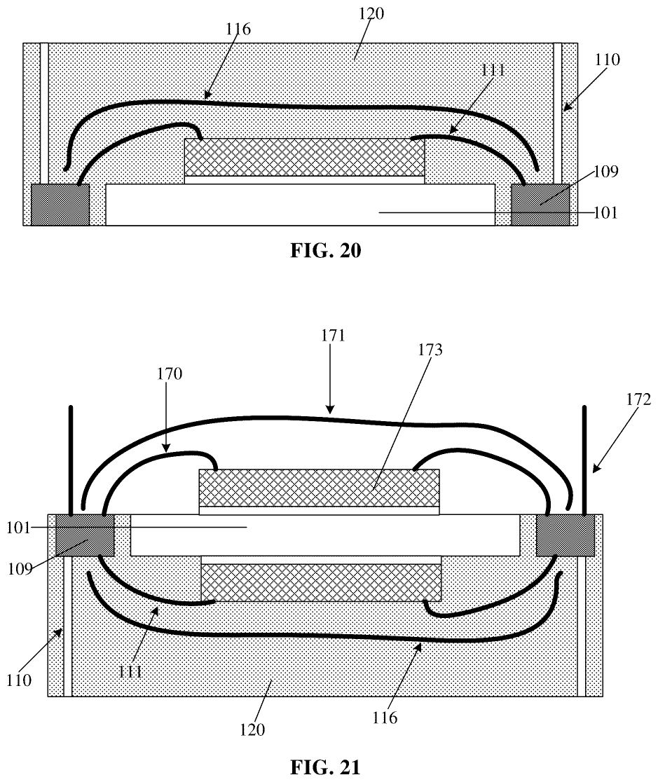

Referring to FIG. 20, after forming the first conductive wire 116, the second conductive wire 111, and the first conductive structure 110, and before subsequently providing the second chip on the second surface 160 of the base 101, it further comprises forming, on the first surface 103 of the lead frame 100, a first molding layer 120 covering the first conductive wire 116, the second conductive wire 111, the first conductive structure 110, and the first chip.

Specifically, the first molding layer 120 is used to envelop the first conductive wire 116, the second conductive wire 111, the first conductive structure 110, and the first chip on the first surface 103, and to provide protection for the first conductive wire 116, the second conductive wire 111, the first conductive structure 110, and the first chip, and at the same time it reduces the probability of the first conductive wire 116, the second conductive wire 111, and the first conductive structure 110 cross-talk with each other, and also reduces the probability that the first conductive wire 116, the second conductive wire 111, the first conductive structure 110 and the first chip are contaminated.

In the present embodiment, the material of the first molding layer 120 comprises a molding compound. Specifically, the material of the molding compound comprises an epoxy resin, and the epoxy resin has the advantages of low shrinkage, good adhesion, good corrosion resistance, excellent electrical properties, low cost, etc. It should be noted that the material of the molding compound may also comprise one or more of a hardener, a catalyst, and a filler.

Referring to FIG. 21, a second chip 173 is provided on the second surface 160 of the base 101; a plurality of third conductive wires 171 spanning the second chip 173 are formed on the second surface 160 of the lead frame 100, two ends of the third conductive wires 171 being electrically connected with the first lead 102, respectively; a fourth conductive wire 170 is formed on the second surface 160 of the lead frame 100, one end of the fourth conductive wire 170 being electrically connected with the second chip 173, and the other end of the fourth conductive wire 170 being electrically connected with the second lead 109; a second conductive structure 172 is formed on the second surface 160 of the second lead 109, the second conductive structure 172 being electrically connected with the second lead 109.

It should be noted that the second chip 173 is used to meet the performance needs of the package structure. Specifically, the second chip 173 may be selected to have different functions according to the performance needs of the package structure.

It should also be noted that the plurality of third conductive wires 171 approximately form a continuous conductive surface, which has the ability to block electromagnetic wave penetration, thus reducing the probability that the second chip 173 undergoes electromagnetic interference, and at the same time, in the subsequent formation of the second molding layer, the second molding layer is able to cover the plurality of third conductive wires 171; in comparison with the solution of providing an electromagnetic shielding at the periphery of the second molding layer, the molding layer according to embodiments of the present disclosure covers the plurality of third conductive wires 171, so that the plurality of third conductive wires 171 is located in the second molding layer, the plurality of third conductive wires 171 provide electromagnetic shielding effect, and at the same time can reduce the thickness of the package structure, which is conducive to the miniaturization of the volume of the package structure, thereby improving the performance of the package structure.

Moreover, by forming the third conductive wire 171 on the second surface 160, both the first surface 103 and the second surface 160 of the package structure have the function of electromagnetic shielding.

In the present embodiment, in the step of forming the third conductive wire 171, the third conductive wire 171 comprises a third sub conductive wire (not shown) extending in a first direction and a fourth sub conductive wire (not shown) extending in a second direction, the first direction being perpendicular to the second direction.

It should be noted that the third sub conductive wire and the fourth sub conductive wire are perpendicular to each other, which means that a continuous conductive surface extending along the first direction and a continuous conductive surface extending along the second direction are formed above the second chip 173, which further reduces the probability of the electromagnetic wave passing through the conductive surface.

In the present embodiment, the third sub conductive wire and the fourth sub conductive wire located above the second chip 173 are orthogonal to each other.

Specifically, the third sub conductive wire and the fourth sub conductive wire located above the second chip 173 are orthogonal to each other, which means that the formation of a conductive surface with a grid-like shape above the second chip 173 is capable of forming an electromagnetic shielding layer above the second chip 173, this electromagnetic shielding layer is capable of blocking the electromagnetic waves from penetrating, and reducing the probability of the second chip 173 being subjected to electromagnetic interference.

It should be noted that as shown in FIG. 21, the first conductive wire 116 is shown for ease of illustration, the first conductive wire 116 is not electrically connected with the second lead 109, and the first conductive wire 116 is electrically connected with the first lead 102.

It should be noted that one end of the fourth conductive wire 170 is used to be electrically connected with the second chip 173, and the other end of the fourth conductive wire 170 is electrically connected with the second lead 109, thereby enabling the second chip 173 to be electrically connected with an external circuit carrier board via the fourth conductive wire 170 and the second lead 109.

In the present embodiment, the second conductive structure 172 comprises a conductive wire.

Specifically, when the first conductive structure 110 is a conductive wire, the third conductive wire 171, the fourth conductive wire 170, and the second conductive structure 172 are formed in the same step.

In other embodiments, the second conductive structure 172 may also comprise an electrical connection pillar.

Specifically, when the second conductive structure 172 is an electrical connection pillar, the third conductive wire 171 and the fourth conductive wire 170 are formed in the same step; after forming the third conductive wire 171 and the fourth conductive wire 170, the second conductive structure 172 is formed on the first surface 103 of the second lead 109.

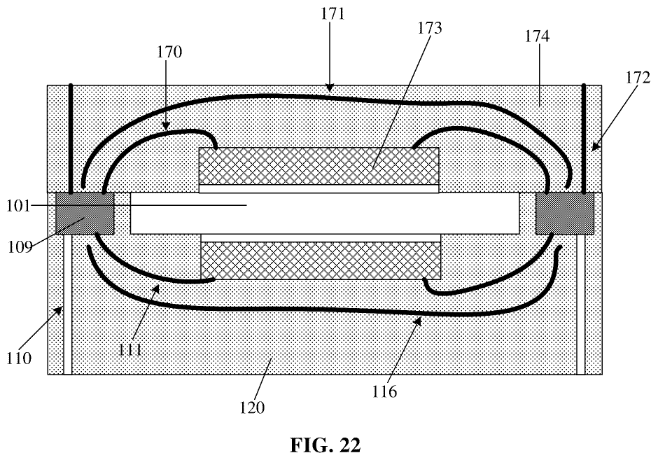

Referring to FIG. 22, after forming the third conductive wire 171, the fourth conductive wire 170, and the second conductive structure 172, it further comprises forming a second molding layer 174 covering the third conductive wire 171, the fourth conductive wire 170, the second conductive structure 172, and the second chip 173 on the second surface 160 of the lead frame 100.

Specifically, the second molding layer 174 is used to envelop the third conductive wire 171, the fourth conductive wire 170, the second conductive structure 172, and the second chip 173 on the second surface 160, thus providing protection for the third conductive wire 171, the fourth conductive wire 170, the second conductive structure 172, and the second chip 173, and at the same time reducing the probability that the third conductive wire 171, the fourth conductive wire 170, and the second conductive structure 172 cross-talk with each other, and also reducing the probability that the third conductive wire 171, the fourth conductive wire 170, the second conductive structure 172 and the second chip 173 are contaminated.

In the present embodiment, one end of the second conductive structure 172 is exposed from the second molding layer 174. Specifically, one end of the second conductive structure 172 away from the second lead 109 is exposed from the second molding layer 174, and the second chip 173 may be electrically connected with an external circuit carrier board or other circuit components via the second conductive structure 172.

In the present embodiment, the material of the second molding layer 174 comprises a molding compound. Specifically, the material of the molding compound comprises an epoxy resin, and the epoxy resin has the advantages of low shrinkage, good adhesion, good corrosion resistance, excellent electrical properties, low cost, etc. It should be noted that the material of the molding compound may also comprise one or more of a hardener, a catalyst, and a filler.

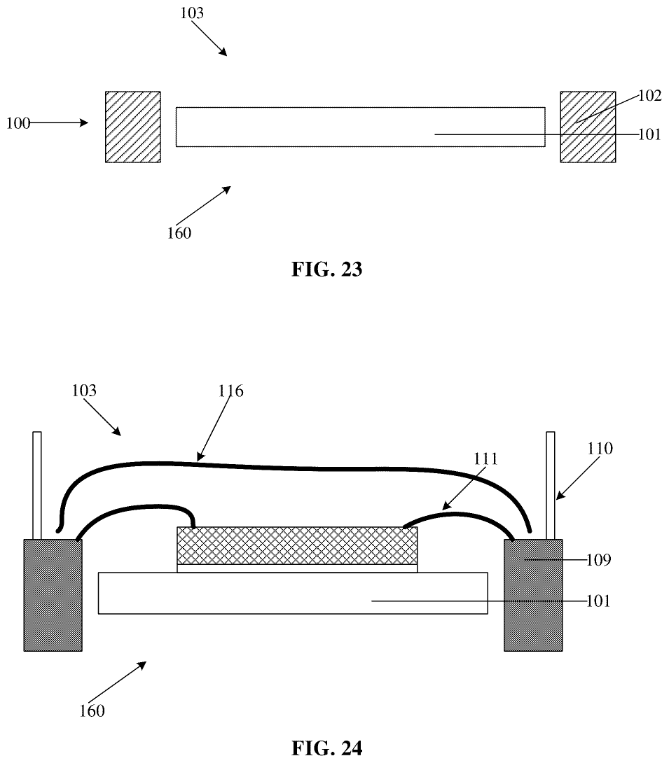

FIGS. 23-26 are structural schematic diagrams corresponding to each step of the third embodiment of the package method of the present disclosure.

The similar content between the present embodiment and the first embodiment is not repeated herein. The difference between the present embodiment and the first embodiment is that:

Referring to FIG. 23, in the step of providing the lead frame 100, the lead frame 100 further comprises the second surface 160 facing away from the first surface 103. The second surface 160 of the base 101 is higher than the second surface 160 of the first lead 102.

Specifically, the second surface 160 of the base 101 is higher than the second surface 160 of the first lead 102, which means that the thickness of the base 101 is smaller than the thickness of the first lead 102, and in the subsequent process of providing the second chip, the second chip can be located in the lead frame 100, so that the overall height of the lead frame 100 and the second chip can be reduced, thereby further reducing the thickness of the package structure.

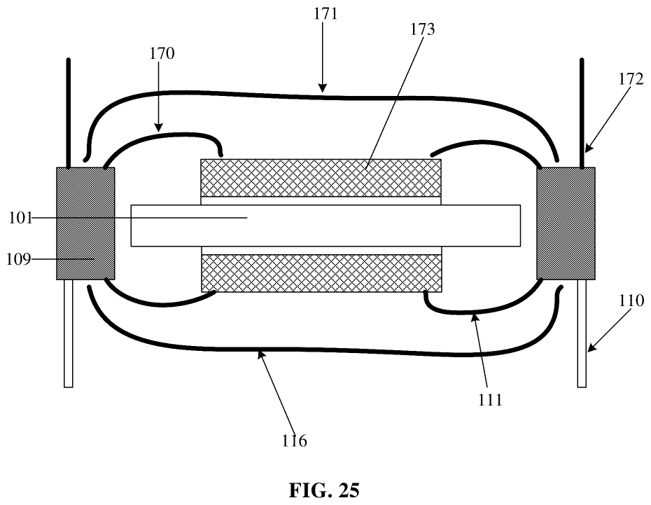

Referring to FIGS. 24-25, after forming the first conductive wire 116, the second conductive wire 111 and the first conductive structure 110, the package method further comprises: providing a second chip 173 on the second surface 160 of the base 101; forming, on the second surface 160 of the lead frame 100, a plurality of third conductive wires 171 spanning the second chip 173, two ends of the third conductive wire 171 being electrically connected with the first lead 102, respectively; forming a fourth conductive wire 170 on the second surface 160 of the lead frame 100, one end of the fourth conductive wire 170 is electrically connected with the second chip 173, and the other end of the fourth conductive wire 170 is electrically connected with the second lead 109; forming a second conductive structure 172 on the second surface 160 of the second lead 109, the second conductive structure 172 being electrically connected with the second lead 109.

It should be noted that the second chip 173 is used to meet the performance needs of the package structure. Specifically, the second chip 173 may be selected to have different functions according to the performance needs of the package structure.

It should also be noted that the plurality of third conductive wires 171 approximately form a continuous conductive surface, the continuous conductive surface has the ability to block electromagnetic wave penetration, reducing the probability that the second chip 173 is subjected to electromagnetic interference, and at the same time, in the subsequent formation of the second molding layer, the second molding layer is able to cover the plurality of third conductive wires 171; compared to the solution of providing an electromagnetic shielding cover at the periphery of the second molding layer, the molding layer according to embodiments of the present disclosure covers the plurality of third conductive wires 171, so that the plurality of third conductive wires 171 is located in the second molding layer, and the plurality of third conductive wires 171 can reduce the thickness of the package structure while providing electromagnetic shielding effect, which is conducive to the miniaturization of the volume of the package structure and thus improves the performance of the package structure.

Moreover, by forming the third conductive wire 171 on the second surface 160, both the first surface 103 and the second surface 160 of the package structure have the function of electromagnetic shielding.

In the present embodiment, in the step of forming the third conductive wire 171, the third conductive wire 171 comprises a third sub conductive wire (not shown) extending in a first direction and a fourth sub conductive wire (not shown) extending in a second direction, the first direction being perpendicular to the second direction.

It should be noted that the third sub conductive wire and the fourth sub conductive wire are perpendicular to each other, which means that a continuous conductive surface extending along the first direction and a continuous conductive surface extending along the second direction are formed above the second chip 173, which further reduces the probability of the electromagnetic wave passing through the conductive surface.

In the present embodiment, the third sub conductive wire and the fourth sub conductive wire located above the second chip 173 are orthogonal to each other.

Specifically, the third sub conductive wire and the fourth sub conductive wire located above the second chip 173 are orthogonal to each other, which means that the formation of a conductive surface with a grid-like shape above the second chip 173 is capable of forming an electromagnetic shielding layer above the second chip 173, and this electromagnetic shielding layer is capable of blocking the electromagnetic waves from penetrating, and reducing the probability of the second chip 173 being subjected to electromagnetic interference.

It should be noted that, as shown in FIG. 24, the first conductive wire 116 is shown for ease of illustration, the first conductive wire 116 is not electrically connected with the second lead 109, and the first conductive wire 116 is electrically connected with the first lead 102.

It should also be noted that, as shown in FIG. 24, a third conductive wire 171 is shown for ease of illustration. The third conductive wire 171 is not electrically connected with the second lead 109, and the third conductive wire 171 is electrically connected with the first lead 102.

It should be noted that one end of the fourth conductive wire 170 is used to be electrically connected with the second chip 173, and the other end of the fourth conductive wire 170 is electrically connected with the second lead 109, thereby enabling the second chip 173 to be electrically connected with an external circuit carrier board via the fourth conductive wire 170 and the second lead 109.

In the present embodiment, the second conductive structure 172 comprises a conductive wire.

Specifically, when the first conductive structure 110 is a conductive wire, the third conductive wire 171, the fourth conductive wire 170, and the second conductive structure 172 are formed in the same step.

In other embodiments, the second conductive structure 172 may also comprise an electrical connection pillar.

Specifically, when the second conductive structure 172 is an electrical connection pillar, the third conductive wire 171 and the fourth conductive wire 170 are formed in the same step; after forming the third conductive wire 171 and the fourth conductive wire 170, the second conductive structure 172 is formed on the first surface 103 of the second lead 109.

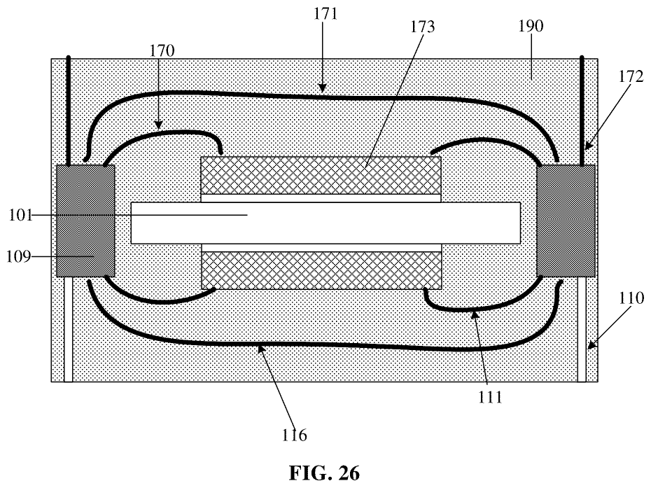

Referring to FIG. 26, after forming the third conductive wire 171, the fourth conductive wire 170, and the second conductive structure 172, the package method further comprises forming a third molding layer 190 on the first surface 103 and the second surface 160, the third molding layer 190 covering the first conductive wire 116, the second conductive wire 111, the first conductive structure 110, and the first chip on the first surface 103, and covering the third conductive wire 171, the fourth conductive wire 170, the second conductive structure 172 and the second chip 173 on the second surface 160.

Specifically, the third molding layer 190 is used to envelop the first surface 103 and the second surface 160, and to provide protection for the first conductive wire 116, the second conductive wire 111, the first conductive structure 110, and the first chip on the first surface 103, and the third conductive wire 171, the fourth conductive wire 170, the second conductive structure 172, and the second chip 173 on the second surface 160, and at the same time to reduce the probability of the first conductive wire 116, the second conductive wire 111 and the first conductive structure 110, and the third conductive wire 171, the fourth conductive wire 170 and the second conductive structure 172 cross-talk with each other. It should be noted that the third molding layer 190 on the first surface 103 and the second surface 160 are formed in the same step, which can reduce the process steps, reduce the process cost, and have higher process compatibility.

In the present embodiment, the third molding layer 190 comprises a molding compound. Specifically, the material of the molding compound comprises an epoxy resin, and the epoxy resin has the advantages of low shrinkage, good adhesion, good corrosion resistance, excellent electrical properties, low cost, etc. It should be noted that the material of the molding compound may also comprise one or more of a hardener, a catalyst, and a filler.

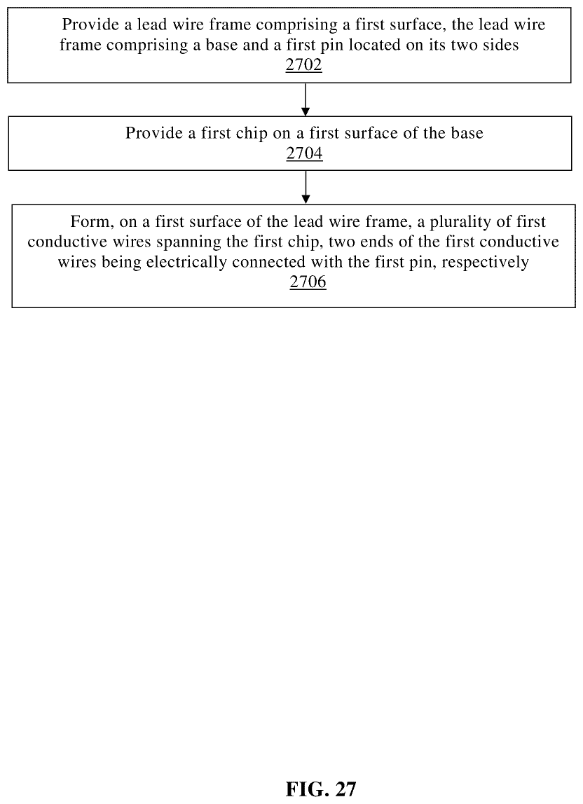

FIG. 27 is a flow chart of a package method of the present disclosure. At operation 2702, a lead frame 100 including a first surface 103 is provided. The lead frame 100 includes a base 101 and a first lead 102 located on its two sides. At operation 2704, a first chip 106 is provided on a first surface of the base 101. At operation 2706, a plurality of first conductive wires 216 spanning the first chip 106 are formed on the first surface 103 of the lead frame 100. Two ends of the first conductive wires 216 are electrically connected with the first lead 102, respectively.

Although the present disclosure is disclosed as above, the present disclosure is not limited thereto. Any person skilled in the art may make various changes and modifications without departing from the spirit and scope of the present disclosure, and therefore the scope of protection of the present disclosure shall be defined by the scope limited by the claims.

What is claimed is:

1. A package structure, comprising:
a lead frame comprising a first surface, wherein the lead frame comprises a base and first leads located on its four sides;
a first chip provided on a first surface of the base; and
a first conductive wire located on a first surface of the lead frame and spanning the first chip, two ends of the first conductive wire being electrically connected with the first leads on opposing two sides of the base.

2. The package structure according to claim 1, wherein a first surface of the base is lower than a first surface of the first lead, or the first surface of the base is flush with the first surface of the first lead.

3. The package structure according to claim 1, wherein
the lead frame further comprises a second lead, the second lead being located between two adjacent first leads;
the package structure further comprises a second conductive wire located on a first surface of the lead frame, one end of the second conductive wire electrically connected with the first chip, and the other end of the second conductive wire electrically connected with the second lead; and
a first conductive structure is located on a first surface of the second lead, the first conductive structure being electrically connected with the second lead.

4. The package structure according to claim 3, wherein the first conductive structure comprises a conductive wire or an electrical connection pillar.

5. The package structure according to claim 3, further comprising:
a first molding layer located on a first surface of the lead frame and covering the first conductive wire, the second conductive wire, the first conductive structure, and the first chip.

6. The package structure according to claim 5, wherein an end of the first conductive structure away from the second lead is exposed from the first molding layer.

7. The package structure according to claim 1, wherein the first conductive wire comprises a first sub conductive wire extending in a first direction and a second sub conductive wire extending in a second direction, the first direction being perpendicular to the second direction.

8. The package structure according to claim 3, wherein
the lead frame further comprises a second surface facing away from the first surface, the second surface of the base being higher than the first surface of the first lead, or the second surface of the base being flush with the second surface of the first lead; and
the package structure further comprises:
a second chip, provided on a second surface of the base;
a third conductive wire located on a second surface of the lead frame and spanning the second chip, two ends of the third conductive wire being electrically connected with the first leads, respectively;
a fourth conductive wire located on a second surface of the lead frame, one end of the fourth conductive wire being electrically connected with the second chip and the other end of the fourth conductive wire being electrically connected with the second lead; and
a second conductive structure located on a second surface of the second lead, the second conductive structure being electrically connected with the second lead.

9. The package structure according to claim 8, further comprising:
a second molding layer located on a second surface of the lead frame and covering the third conductive wire, the fourth conductive wire, the second conductive structure, and the second chip and exposing an end of the second conductive structure away from the second lead.

10. The package structure according to claim 8, wherein the second conductive structure comprises a conductive wire or an electrical connection pillar.

11. The package structure according to claim 8, wherein the third conductive wire comprises a third sub conductive wire extending in a first direction and a fourth sub conductive wire extending in a second direction, the first direction being perpendicular to the second direction.

12. A package method, comprising:
providing a lead frame comprising a first surface, the lead frame comprising a base and a first lead located on its two sides;
providing a first chip on a first surface of the base; and
forming, on the first surface of the lead frame, a plurality of first conductive wires spanning the first chip, two ends of the first conductive wires being electrically connected with the first lead, respectively.

13. The package method according to claim 12, wherein in providing the lead frame, a first surface of the base is lower than a first surface of the first lead, or a first side of the base is flush with a first side of the first lead.

14. The package method according to claim 12, wherein in providing the lead frame, the lead frame further comprises a second lead, the second lead being located on a side of the base and the first lead; and
the package method further comprises:
forming, on a first surface of the lead frame, a second conductive wire, one end of the second conductive wire being electrically connected with the first chip, and the other end of the second conductive wire being electrically connected with the second lead; and
forming a first conductive structure on a first surface of the second lead, the first conductive structure being electrically connected with the second lead.

15. The package method according to claim 14, wherein the first conductive structure comprises a conductive wire or an electrical connection pillar.

16. The package method according to claim 15, wherein
when the first conductive structure is a conductive wire, the first conductive wire, the second conductive wire, and the first conductive structure are formed in the same step; or when the first conductive structure is an electrical connection pillar, the first conductive wire and the second conductive wire are formed in the same step; and
after forming the first conductive wire and the second conductive wire, a first conductive structure is formed on a first surface of the second lead.

17. The package method according to claim 14, further comprising:
forming a first molding layer covering the first conductive wire, the second conductive wire, the first conductive structure, and the first chip on a first surface of the lead frame; and
after forming the first molding layer, the package method further comprises:
providing a carrier board;
orienting a first surface of the lead frame toward the carrier board; and
placing, on the carrier board, a package module comprising the lead frame, the first chip, and the molding layer, and the surface of the base facing away from the first surface is exposed from the first molding layer.

18. The package method according to claim 12, wherein in forming the first conductive wire, the first conductive wire comprises a first sub conductive wire extending in a first direction and a second sub conductive wire extending in a second direction, the first direction being perpendicular to the second direction.

19. The package method according to claim 14, wherein
in providing the lead frame, the lead frame further comprises a second surface facing away from the first surface, the second surface of the base being higher than the second surface of the first lead, or the second surface of the base being flush with the second surface of the first lead; and
after forming the first conductive wire, the second conductive wire, and the first conductive structure, the package method further comprises:
providing a second chip on the second surface of the base;
forming, on the second surface of the lead frame, a plurality of third conductive wires spanning the second chip, the two ends of the third conductive wires being electrically connected with the first lead, respectively; and
forming a fourth conductive wire on the second surface of the lead frame, one end of the fourth conductive wire being electrically connected with the second chip, the other end of the fourth conductive wire being electrically connected with the second lead; and
a second conductive structure is formed on the second surface of the second lead, the second conductive structure being electrically connected with the second lead.

20. The package method according to claim 19, wherein
after forming the first conductive wire, the second conductive wire, and the first conductive structure, and before providing a second chip on the second surface of the base, the method further comprises:
forming, on the first surface of the lead frame, a first molding layer covering the first conductive wire, the second conductive wire, the first conductive structure, and the first chip; and
after forming the third conductive wire, the fourth conductive wire, and the second conductive structure, the method further comprises:
forming, on the second surface of the lead frame, a second molding layer covering the third conductive wire, the fourth conductive wire, the second conductive structure, and the second chip.
